(19) United States
(12) Patent Application Publication
(10) Pub. No.: US 2017/0170016 A1
(43) Pub. Date: Jun. 15, 2017

(54) MULTIPLE PATTERNING METHOD FOR SUBSTRATE

(71) Applicant: GLOBALFOUNDRIES INC., Grand Cayman (KY)

(72) Inventors: Woo-Hyeong Lee, Poughquag, NY (US); Jujin An, Fishkill, NY (US); Shahrukh A. Khan, Danbury, CT (US); Rosa A. Orozco-Teran, Wappingers Falls, NY (US); Oluwafemi O. Ogunsola, Hopewell Junction, NY (US); William K. Henson, Hopewell Junction, NY (US); Scott R. Stiffler, Sharon, CT (US)

(21) Appl. No.: 14/967,755

(22) Filed: Dec. 14, 2015

(51) Int. Cl. H01L 21/033; H01L 21/8238; H01L 21/027

(52) U.S. Cl. CPC H01L 21/0338; H01L 21/0276; H01L 21/0332; H01L 21/0335; H01L 21/0337; H01L 21/823871

(57) ABSTRACT

Methods for multiple patterning a substrate may include: forming a hard mask including a carbonaceous layer and an oxynitride layer over the carbonaceous layer on a substrate; and forming a first pattern into the oxynitride layer and partially into the carbonaceous layer using a first soft mask positioned over the hard mask. A wet etching removes a portion of the first soft mask from the first pattern in the oxynitride layer without damaging the carbonaceous layer. Subsequently, a second pattern and a third pattern are formed into the hard mask, creating a multiple pattern in the hard mask. The multiple pattern may be etched into the substrate, followed by removing any remaining portion of the hard mask.

### BACKGROUND

Technical Field

The present disclosure relates to semiconductor fabrication, and more specifically, to a method for multiple patterning a single level of a substrate.

Related Art

As complementary metal-oxide semiconductor (CMOS) technologies continue to scale down in size, creating smaller structures with conventional patterning techniques has become more challenging. One particular challenge is pattern bridging between adjacent elements to be created in an underlying structure. Pattern bridging occurs because pitch between elements has become increasingly small such that insufficient distance is provided in the material, causing merging of openings and other bridging problems.

In order to address the pattern bridging issue, patterning schemes have been introduced that employ multiple patterns to separate (decompose) adjacent patterns within the same level. That is, a first pattern is employed to generate a first set of openings, and one or more patterns are used to generate subsequent sets of openings. Multiple pattern schemes for a single layer, however, present additional issues. For example, multiple pattern schemes may result in degradation in yield of properly created openings because subsequent patterns damage the previously created openings, cap layers, masks, etc. Consequently, pattern fidelity and also roughness are oftentimes inadequate. Another challenge is that current multiple pattern schemes employ soft masks (e.g., a tri-layer soft mask including photoresist over silicon anti-reflective coating (SiARC) over optical planarization layer (OPL)) which are incapable of further scaling of critical dimensions (CD) and creating proper line edge roughness (LER).

### SUMMARY

A first aspect of the disclosure is directed to a method for multiple patterning a substrate, the method comprising: forming a hard mask including a carbonaceous layer and an oxynitride layer over the carbonaceous layer on a substrate; forming a first pattern into the oxynitride layer and partially into the carbonaceous layer using a first soft mask positioned over the hard mask; wet etching to remove a portion of the first soft mask, the wet etching removing the portion of the first soft mask from the first pattern in the oxynitride layer without damaging the carbonaceous layer; forming a second pattern into the hard mask; forming a third pattern into the hard mask, creating a multiple pattern in the hard mask; etching the multiple pattern into the substrate; and removing any remaining portion of the hard mask.

A second aspect of the disclosure includes a multiple patterning method comprising: forming a hard mask including a carbonaceous layer and an oxynitride layer over the carbonaceous layer on a substrate having a cap layer; forming a first pattern into the oxynitride layer and partially into the carbonaceous layer using a first soft mask positioned over the hard mask; wet etching to remove a portion of the first soft mask, the wet etching removing the portion of the first soft mask from the first pattern in the oxynitride layer without damaging the carbonaceous layer; forming a second pattern through the oxynitride layer and partially into the carbonaceous layer using a second soft mask positioned over the hard mask; removing the second soft mask; etching the first pattern and the second pattern at least partially into the cap layer using and the oxynitride layer and the carbonaceous layer; forming a third pattern partially into the substrate using a third soft mask, forming a multiple pattern in the carbonaceous layer; etching the multiple pattern into the substrate; and removing any remaining portion of the hard mask.

A third aspect of the disclosure relates to a multiple patterning method comprising: forming a hard mask including a carbonaceous layer and an oxynitride layer over the carbonaceous layer on a substrate having a cap layer, the cap layer including an oxide layer over a nitride layer; forming a first contact pattern into the oxynitride layer and partially into the carbonaceous layer using a first soft mask positioned over the hard mask; wet etching to remove a portion of the first soft mask, the wet etching removing the portion of the first soft mask from the first contact pattern in the oxynitride layer without damaging the carbonaceous layer; forming a second contact pattern through the oxynitride layer and partially into the carbonaceous layer using a second soft mask positioned over the hard mask; removing the second soft mask; etching the first contact pattern and the second contact pattern to the nitride layer using the oxynitride layer and the carbonaceous layer; patterning a third through silicon via (TSV) pattern partially into the substrate using a third soft mask, forming a multiple pattern in the carbonaceous layer; removing the third soft mask; etching the multiple pattern into the substrate, forming openings for a first and second contact and a TSV; and removing any remaining portion of the hard mask.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a substrate undergoing a step of a method according to embodiments of the disclosure.

FIG. 2 shows a cross-sectional view of a substrate undergoing a step of a method according to embodiments of the disclosure.

FIG. 3 shows a cross-sectional view of a substrate undergoing a step of a method according to embodiments of the disclosure.

FIG. 4 shows a cross-sectional view of a substrate undergoing a step of a method according to embodiments of the disclosure.

FIG. 5 shows a cross-sectional view of a substrate undergoing a step of a method according to embodiments of the disclosure.

FIG. 6 shows a cross-sectional view of a substrate undergoing a step of a method according to embodiments of the disclosure.

FIG. 7 shows a cross-sectional view of a substrate undergoing a step of a method according to embodiments of the disclosure.

### DETAILED DESCRIPTION

Methods for multiple patterning a substrate are disclosed herein that avoid current pattern bridging issues in a single level of a substrate. Embodiments of the method employ steps to create a hard mask that is capable of creating a multiple pattern that can create advanced critical dimensions with proper line edge roughness. In embodiments of the disclosure, the hard mask may include an oxynitride cap layer (single layer) over a carbonaceous layer such as amorphous carbon. Although a single layer cap is provided over the carbonaceous layer, embodiments of the method employ a wet etch to remove a portion of the soft mask from a pattern in the oxynitride layer without damaging the carbonaceous layer. Subsequently, a second pattern and a third pattern are formed into the hard mask, creating a multiple pattern in the hard mask. The multiple pattern may be etched into the substrate, followed by the removal of any remaining portion of the hard mask.

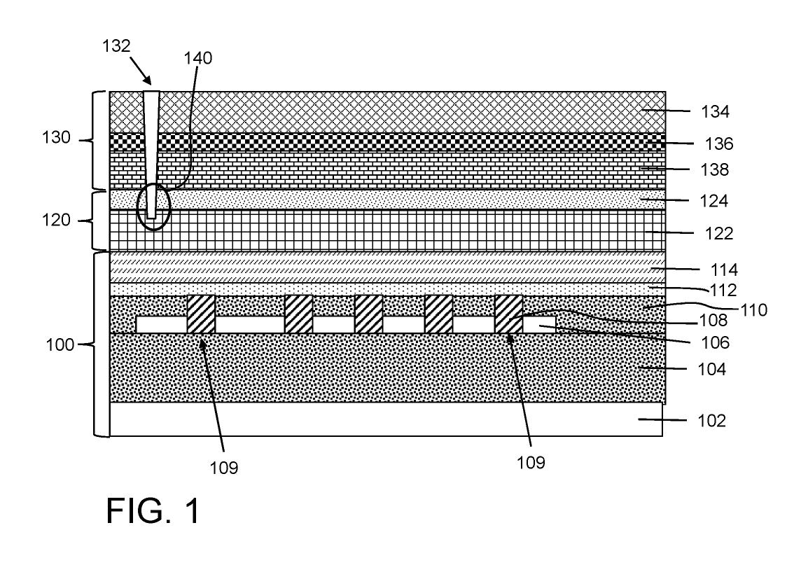

Referring to the drawings, details of embodiments of the methods will now be described. FIG. 1 shows a cross-sectional view of an example precursor substrate 100 upon which methods according to embodiments of the disclosure will be applied. Substrate 100, in the example illustrated, includes a semiconductor-on-insulator (SOI) substrate. SOI typically refers to the use of a layered semiconductor-insulator-semiconductor substrate in place of a more conventional semiconductor substrate (e.g., bulk silicon substrate) in semiconductor manufacturing. SOI-based devices differ from conventional semiconductor-built devices in that the semiconductor junction is above an electrical insulator. Substrate 100 includes a semiconductor layer 102 with a buried insulator layer 104 thereover. Buried insulator layer 104 may include, for example, silicon dioxide, sapphire, etc. The choice of insulator depends largely on intended, application, with sapphire being used for radiation-sensitive applications and silicon dioxide preferred for improved performance and diminished short channel effects in microelectronic devices.

Semiconductor-on-insulator (SOI) layer 106 is over buried insulator layer 104. In the example shown, SOI layer 106 has been formed into fins upon which metal gates 108 have been formed, creating transistors 109 below a cap layer(s) 112, 114 (optional). It is understood that SOI layer 106 may take a variety of alternative forms. The precise thickness of insulating layer 104 and topmost SOI layer 106 also vary widely with the intended application. In one example, SOI layer 106 may be approximately 20-30 nanometers (nm), and insulator layer 104 may be approximately 180-200 nm. As used herein with reference to layer thicknesses, “approximately” indicates +/−10% on either end of the range.

Semiconductor layer 102 and/or SOI layer 106 may include but are not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor substrate may be strained. For example, SOI layer 106 may be strained.

Substrate 100 may also include an interlayer dielectric (ILD) layer 110 over/around metal gates 108 and semiconductor layer 106. ILD layer 110 may include but is not limited to: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, SiLK (a polyarylene ether available from Dow Chemical Corporation), a spin-on silicon-carbon containing polymer material available from JSR Corporation, other low dielectric constant (<3.9) material, or layers thereof. One or more cap layers 112, 114 may be provided over ILD layer 110. In the example shown, cap layer 112 may include silicon nitride (Si₃N₄) and cap layer 114 may include silicon dioxide (SiO₂) such as tetraethyl orthosilicate, Si(OC₂H₅)₄ (TEOS) oxide. In one example, ILD layer 110 (and metal gates 108) may be approximately 70-80 nm thick, cap layer 112 may be approximately 15-25 nm, and cap layer 114 may be approximately 85-95 nm.

Any of the above-described layers of substrate 100 may be formed using any now known or later developed processing such as depositing, patterning, etching, planarization, etc. As used herein, “depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While a particular example of substrate 100 has been illustrated, it is emphasized that teachings of the disclosure that follow herein may be applied to a wide variety of alternative substrates.

As also shown in FIG. 1, according to embodiments of the disclosure, a hard mask 120 may be formed over substrate 100. In one embodiment, hard mask 120 includes a carbonaceous layer 122 and a silicon oxynitride (SiON) layer 124 over carbonaceous layer 122. In one embodiment, carbonaceous layer 122 includes amorphous carbon. In one example, silicon oxynitride layer 124 (hereinafter “oxynitride layer 124”) may have a thickness of approximately 35-45 nm, and carbonaceous layer 122 may have a thickness of approximately 130-140 nm. As will be described herein, carbonaceous layer 122 for further scaling of critical dimensions and improved line edge roughness in the multiple pattern schemed described herein. In this regard, carbonaceous layer 122 provides a stable mask material capable of patterning features with sub-minimum half pitch and sub-minimum CD. Carbonaceous layer 122 and oxynitride layer 124 may be formed using, for example, CVD, PECVD, etc.

FIG. 1 also shows forming a first soft mask 130 over hard mask 120. Soft mask 130 is used in lithographically forming a first pattern 132 into hard mask 120, namely oxynitride layer 124 and partially into carbonaceous layer 122. In lithography (or “photolithography”), a radiation sensitive “photoresist” 134 is formed over one or more layers which are to be treated, in some manner, such as to be selectively doped and/or to have a pattern transferred thereto. The resist is itself first patterned by exposing it to radiation, where the radiation (selectively) passes through an intervening mask or template containing the pattern. As a result, the exposed or unexposed areas of photoresist 134 become more or less soluble, depending on the type of photoresist used. A developer is then used to remove the more soluble areas of the resist leaving a patterned photoresist. The patterned photoresist can then serve as a mask for the underlying layers which can then be selectively treated, such as to undergo etching, for example.

While any now known or later developed soft mask may be employed, in the example shown, soft mask 130 may include photoresist 134 over an anti-reflective coating (ARC) layer 136 over an optical planarization layer (OPL) 138. Each layer 134, 136, 138 may include any now known or later developed form of the respective material. With regard to ARC layer 136, in one embodiment, ARC layer 136 may include a silicon ARC layer. In one example, photoresist 134 may have a thickness of approximately 90-130 nm, ARC layer 136 may have a thickness of approximately 30-40 nm, and OPL 138 may have a thickness of approximately 120-150 nm. As will be apparent to those with skill in the art, in the example shown, first pattern 132 includes an opening for a first contact (not shown in FIG. 1) to a transistor 109 (leftmost transistor), e.g., to one of the source or drain regions of the transistor as will be described herein. While only one opening is illustrated, it is understood that any number of openings may be created by pattern 132.

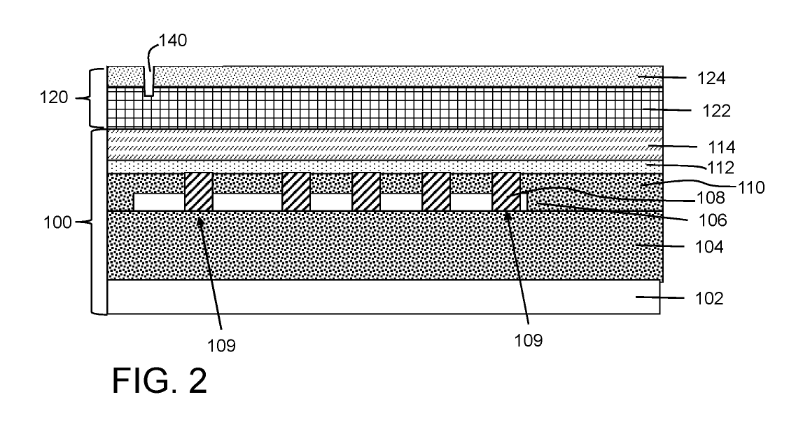

FIG. 2 shows wet etching to remove a portion first soft mask 130 (FIG. 1). Notably, in contrast to conventional reactive ion etching (RIE) processes that would typically be used to remove soft mask 130 (FIG. 1), as illustrated, the wet etching removes a portion first soft mask 130 (FIG. 1) from first pattern 132 (FIG. 1) in oxynitride layer 124 without damaging carbonaceous layer 122. As understood, RIE is a variation of plasma etching in which during etching, the semiconductor wafer is placed on an RF powered electrode. The plasma is generated under low pressure (vacuum) by an electromagnetic field. It uses chemically reactive plasma to remove material deposited on wafers. High-energy ions from the plasma attack the wafer surface and react with it. The wafer takes on potential which accelerates etching species extracted from plasma toward the etched surface. A chemical etching reaction is preferentially taking place in the direction normal to the surface--in other words, etching is more anisotropic than in plasma etching but is less selective. Notably, RIE typically leaves the etched surface damaged such that if RIE were used in this setting, it would damage carbonaceous layer 122 of hard mask 120, thus destroying the fidelity of hard mask 120. Wet etching is performed with a chemistry (such as an acid) which may be chosen for its ability to selectively dissolve a given material (such as organic material, OPL), while, leaving another material (such as amorphous carbon) relatively intact. In one embodiment, wet etching may include using a sulfuric acid peroxide mixture.

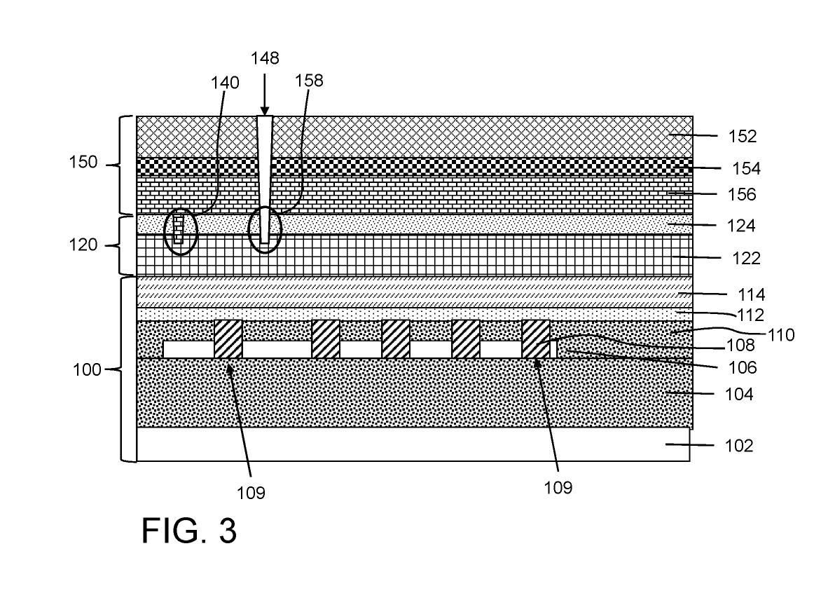

FIG. 3 shows forming a second pattern 148 into hard mask 120. In one embodiment, forming second pattern 148 may include forming second pattern 148 through oxynitride layer 124 and partially into carbonaceous layer 122 using a second soft mask 150 positioned over hard mask 120. If second pattern 148 is to have similar dimensions to first pattern 132, second soft mask 150 may be substantially identical to first soft mask 130 (FIG. 1). That is, second soft mask 150 may include photoresist 152 over ARC layer 154 over OPL 156 having dimensions, etc., as described relative to soft mask 130 (FIG. 1). Here, second pattern 148 includes an opening 158 for a second contact to transistor 109, i.e., on the other of the source or drain regions transistor 109 compared to opening 140. As shown, OPL 156 fills opening 140 in hard mask 120 from first pattern 132 (FIG. 1).

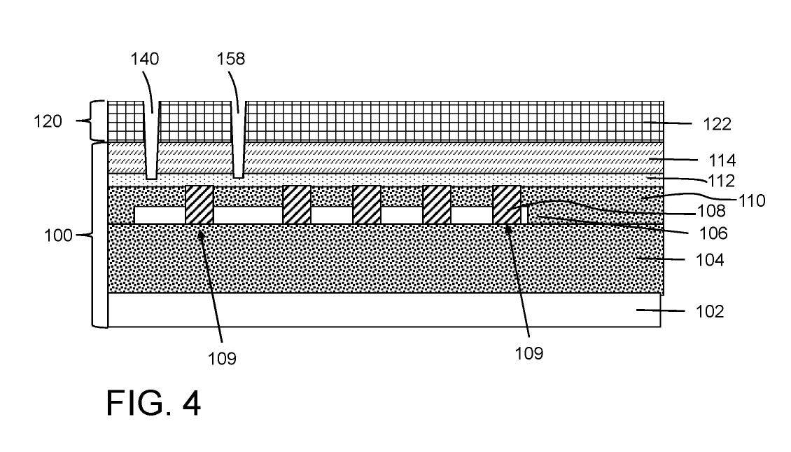

FIG. 4 shows removing second soft mask 150 (FIG. 3). This process may include any now known or later developed etching process, e.g., RIE, wet etching, etc. As this step occurs, as illustrated in FIG. 4, first pattern 132 (FIG. 1) (i.e., opening 140) and second pattern 148 (i.e., opening 158) may also be etched at least partially into cap layer 114 using oxynitride layer 124 (in FIG. 3, removed during etching process) and carbonaceous layer 122 of hard mask 120. In the example shown, both patterns are extended through cap layer 114 and to cap layer 112; however, the patterns may be just into cap layer 114 or partially into cap layer 112. Hereafter, hard mask 120 includes only carbonaceous layer 122.

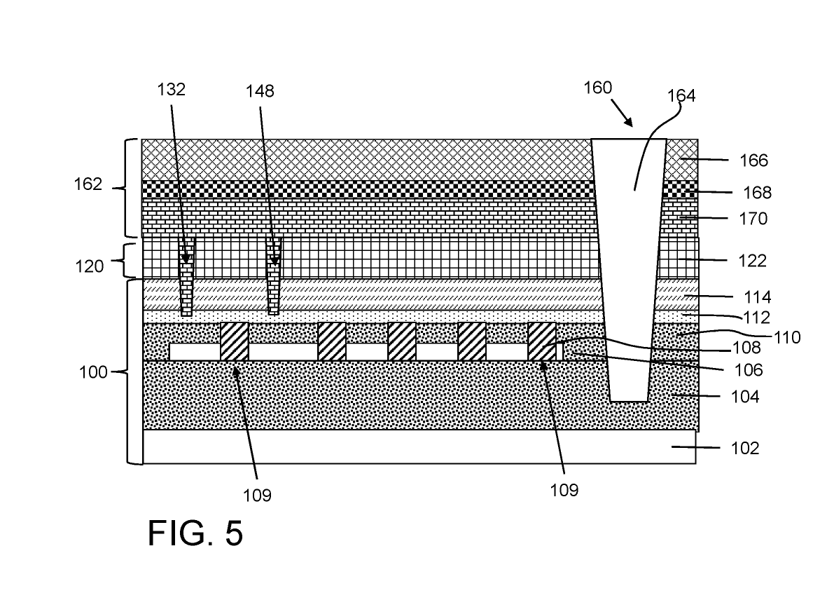

FIG. 5 shows forming a third pattern 160 into hard mask 120, creating a multiple pattern in hard mask 120 (i.e., first, second and third patterns 132, 148, 160). As shown, a third soft mask 162 may be employed to form third pattern 160 partially into substrate 100. In the example shown, third pattern 160 includes an opening 164 for a through silicon via (TSV) (not shown in FIG. 5) to semiconductor substrate 102 of SOI substrate 100 as will be described herein. Third soft mask 162 is used to create opening through hard mask 120, cap layers 112, 114, ILD layer 110 and partially into buried insulator layer 104. Third soft mask 162 may include materials substantially identical to those described relative to first and second masks 130 and 150 (FIGS. 1 and 3). Due to the size of pattern 160, third soft mask 162 may need to be thicker than first and second masks 130 and 150 (FIGS. 1 and 3). For example, photoresist 166 may have a thickness of approximately 190-210 nm, ARC layer 168 may have a thickness of approximately 70-90 nm, and OPL 170 may have a thickness of approximately 190-210 nm. Once third pattern 160 is created, third soft mask 162 (FIG. 5) may be removed using any now known or later developed etching process, e.g., RIE, wet etching, etc. As this step occurs, OPL 170 in first and second pattern 132 and 148 in hard mask 120 and cap layer(s) 114, 112 is removed.

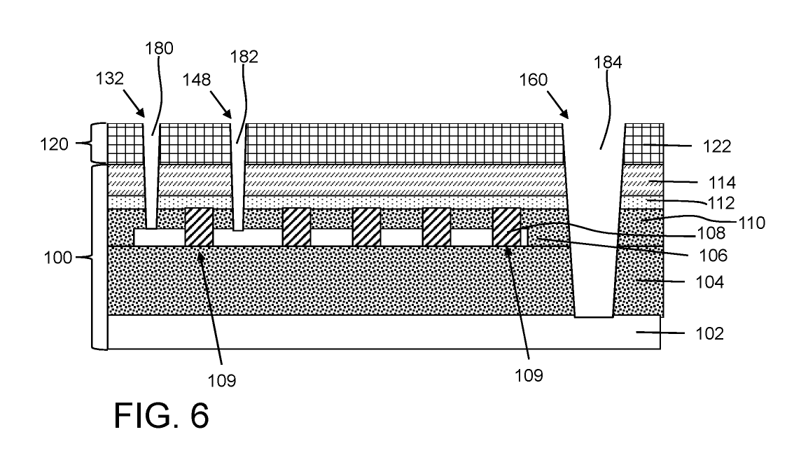

FIG. 6 shows etching the multiple pattern (i.e., first, second and third patterns 132, 148, 160) (further) into substrate 100. The etching may include any now known or later developed etching process, e.g., RIE, wet etching, etc. The example multiple pattern creates a first contact opening 180 to transistor 109 (leftmost), and second opening 182 to transistor 109, and a TSV opening 184 through to semiconductor substrate 102.

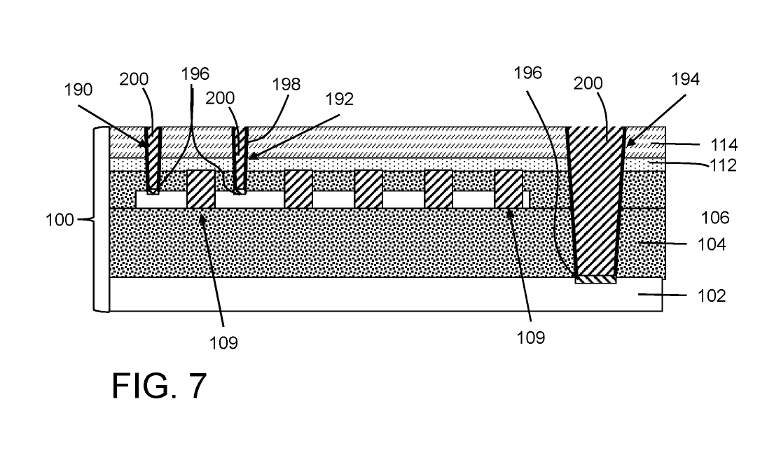

Subsequent processing, as shown in FIG. 7 may include, removing any remaining portion of hard mask 120 (FIG. 6), e.g., using any now known or later developed etching process, e.g., RIE, wet etching, etc., and performing conventional semiconductor processes such as siliciding a bottom of each pattern/opening 180, 182, 184 (FIG. 6) and forming contacts 190, 192 and TSV 194 (FIG. 7) in respective patterns. Silicide 196 may be formed using any now known or later developed technique, e.g., performing an in-situ pre-clean, depositing a metal such as titanium, nickel, cobalt, etc., annealing to have the metal react with silicon, and removing unreacted metal. A refractory metal liner 198 (labeled only once) may then be deposited. The liner may include, for example, ruthenium, tantalum (Ta), titanium (Ti), tungsten (W), iridium (Ir), rhodium (Rh) and platinum (Pt), etc., or mixtures of thereof. A metal 200 such as tungsten, copper, aluminum, etc., may then be deposited, and planarized to arrive at the device shown in FIG. 7.

In this disclosure, hard mask 120 opens contacts made by multiple separated patterning processes together and also improves pattern fidelity as well as scalability. Hard mask 120 employs a single (oxynitride) top layer versus a conventional double layer (oxide and nitride) cap, and so may be a more cost effective. No adhesion failure is observed between oxynitride layer 122 and carbonaceous layer 124 so dense amorphous carbon can be employed, which provides higher patterning fidelity compared to other mask forms. While the teachings of the disclosure have been applied to a particular substrate at a contact level, the teachings can be used anywhere multiple patterning is desired, e.g., different substrate, or not just at a contact level.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for multiple patterning a substrate, the method comprising:
forming a hard mask including a carbonaceous layer and an oxynitride layer over the carbonaceous layer on a substrate;
forming a first pattern into the oxynitride layer and partially into the carbonaceous layer using a first soft mask positioned over the hard mask;
wet etching to remove a portion of the first soft mask, the wet etching removing the portion of the first soft mask from the first pattern in the oxynitride layer without damaging the carbonaceous layer;
forming a second pattern into the hard mask;
forming a third pattern into the hard mask, creating a multiple pattern in the hard mask;
etching the multiple pattern into the substrate; and
removing any remaining portion of the hard mask.

2. The method of claim 1, wherein the substrate includes a cap layer, and further comprising, after forming the second pattern, etching the first pattern and the second pattern at least partially into the cap layer using the carbonaceous layer.

3. The method of claim 1, wherein the forming of the second pattern includes:
forming the second pattern through the oxynitride layer and partially into the carbonaceous layer using a second soft mask positioned over the hard mask; and
removing the second soft mask and the oxynitride layer.

4. The method of claim 3, wherein the forming of the third pattern includes:
forming the third pattern partially into the substrate using a third soft mask; and
removing the third soft mask.

5. The method of claim 4, wherein the substrate further includes a semiconductor-on-insulator (SOI) substrate having a transistor in a semiconductor-on-insulator layer thereof, and a cap layer thereover.

6. The method of claim 5, wherein the first pattern includes an opening for a first contact to the transistor, and the second pattern includes an opening for a second contact to the transistor.

7. The method of claim 5, wherein the third pattern includes an opening for a through silicon via to a semiconductor layer of the SOI substrate.

8. The method of claim 3, wherein at least one of the first, second and third soft masks includes a photoresist over an anti-reflective coating layer over an optical planarization layer.

9. The method of claim 1, wherein the carbonaceous layer includes amorphous carbon.

10. The method of claim 1, wherein the wet etching includes using a sulfuric acid peroxide mixture.

11. The method of claim 1, further comprising:
siliciding a bottom of each pattern; and
forming a contact in each pattern.

12. The method of claim 1, wherein the cap layer includes an oxide layer over a nitride layer.

13. A multiple patterning method comprising:
forming a hard mask including a carbonaceous layer and an oxynitride layer over the carbonaceous layer on a substrate having a cap layer;
forming a first pattern into the oxynitride layer and partially into the carbonaceous layer using a first soft mask positioned over the hard mask;
wet etching to remove a portion of the first soft mask, the wet etching removing the portion of the first soft mask from the first pattern in the oxynitride layer without damaging the carbonaceous layer;
forming a second pattern through the oxynitride layer and partially into the carbonaceous layer using a second soft mask positioned over the hard mask;
removing the second soft mask;
etching the first pattern and the second pattern at least partially into the cap layer using the oxynitride layer and the carbonaceous layer;
forming a third pattern partially into the substrate using a third soft mask, forming a multiple pattern in the carbonaceous layer;
etching the multiple pattern into the substrate; and
removing any remaining portion of the hard mask.

14. The method of claim 13, wherein the substrate further includes a semiconductor-on-insulator (SOI) substrate having a transistor in a semiconductor-on-insulator layer thereof below the cap layer.

15. The method of claim 14, wherein the first pattern includes an opening for a first contact to the transistor, and the second pattern includes an opening for a second contact to the transistor.

16. The method of claim 14, wherein the third pattern includes an opening for a through silicon via to a semiconductor substrate of the SOI substrate.

17. The method of claim 13, wherein at least one of the first, second and third soft masks includes a photoresist over an anti-reflective coating layer over an optical planarization layer.

18. The method of claim 13, wherein the carbonaceous layer includes amorphous carbon.

19. The method of claim 13, wherein the wet etching includes using a sulfuric acid peroxide mixture.

20. A multiple patterning method comprising:
forming a hard mask including a carbonaceous layer and an oxynitride layer over the carbonaceous layer on a substrate having a cap layer, the cap layer including an oxide layer over a nitride layer;
forming a first contact pattern into the oxynitride layer and partially into the carbonaceous layer using a first soft mask positioned over the hard mask;
wet etching to remove a portion of the first soft mask, the wet etching removing the portion of the first soft mask from the first contact pattern in the oxynitride layer without damaging the carbonaceous layer;
forming a second contact pattern through the oxynitride layer and partially into the carbonaceous layer using a second soft mask positioned over the hard mask;
removing the second soft mask;
etching the first contact pattern and the second contact pattern to the nitride layer using the oxynitride layer and the carbonaceous layer;
patterning a third through silicon via (TSV) pattern partially into the substrate using a third soft mask, forming a multiple pattern in the carbonaceous layer;
removing the third soft mask;
etching the multiple pattern into the substrate, forming openings for a first and second contact and a TSV; and
removing any remaining portion of the hard mask.
